(19) United States
(12) Patent Application Publication
(10) Pub. No.: US 2025/0236744 A1
(43) Pub. Date: Jul. 24, 2025

(54) RESIN COMPOSITION FOR MOLDING AND ELECTRONIC COMPONENT DEVICE

(71) Applicant: RESONAC CORPORATION, Tokyo (JP)

(72) Inventor: Masashi YAMAURA, Minato-ku, Tokyo (JP)

(73) Assignee: RESONAC CORPORATION, Tokyo (JP)

(21) Appl. No.: 18/852,501

(22) PCT Filed: Mar. 27, 2023
(86) PCT No.: PCT/JP2023/012350

§ 371 Date: Sep. 30, 2024

(30) Foreign Application Priority Data
Mar. 31, 2022 (WO) PCT/JP2022/016913

(51) Int. Cl. C09D 7/61; C09D 7/63; C09D 7/65; C09D 163/04; H01Q 1/40

(52) U.S. Cl. CPC C09D 7/61; C09D 7/63; C09D 7/65; C09D 163/04; H01Q 1/40

(57) ABSTRACT

The present invention provides a resin composition for molding, the resin composition containing a curable resin, and an inorganic filler that contains silica particles and/or alumina particles, and calcium titanate particles. The content ratio of the calcium titanate particles is not less than 10% by volume but less than 30% by volume relative to the entirety of the inorganic filler; and the content ratio of the entirety of the inorganic filler is more than 60% by volume relative to the entirety of the resin composition for molding.

### TECHNICAL FIELD

The disclosure relates to a resin composition for molding and an electronic component device.

### RELATED ART

In recent years, with the increasing demands for higher functionality, miniaturization, and reduction in thickness and weight of electronic devices, there has been significant progress in the high-density integration and high-density mounting of electronic components. The semiconductor packages used in such electronic devices have been increasing and progressively miniaturized than conventional electronic devices. Furthermore, the frequency of radio waves for communication in electronic devices also becomes higher.

From the perspectives of miniaturization of semiconductor devices and compatibility with high frequencies, high dielectric constant resin compositions used for sealing semiconductor elements have been proposed (see, for example, Japanese Laid-open No. 2015-036410, Japanese Laid-open No. 2017-057268, and Japanese Laid-open No. 2018-141052).

### SUMMARY OF INVENTION

### Issues to be Solved by the Invention

As a material for sealing electronic components, such as semiconductor elements, examples may include resin compositions for molding that include curable resins and inorganic fillers. As the resin composition for molding, when a material with high dielectric loss tangent is used, a transmission signal may easily converted into heat due to transmission loss, and communication efficiency may deteriorate easily. Here, the amount of the transmission loss that occurs due to radio waves transmitted for communication being converted into heat in a dielectric material is represented as the product of the frequency, the square root of the relative dielectric constant, and the dielectric loss tangent. That is, the transmission signal may be easily converted into heat in proportion to its frequency. Also, particularly in reason years, in order to cope with the increase in channel number together with the diversification of information, the frequency of radio waves used for communication is increased. Therefore, a resin composition for molding that is able to form a cured article having a low relative dielectric constant and a low dielectric loss tangent is required. Meanwhile, the greater the relative dielectric constant, the more likely a substrate and a semiconductor package can be miniaturized, etc. From the perspective of suppressing the transmission loss and miniaturizing the substrate, it is desired to secure a low dielectric loss tangent while maintaining the relative dielectric constant by suppressing the relative dielectric constant from excessively increasing and decreasing.

An issue of the disclosure is to provide a resin composition for molding able to mold a cured article having a low dielectric loss tangent while maintaining the relative dielectric constant, as well as an electronic component device using the same.

### Means for Solving the Issues

As the means for solving the issues, the disclosure has the following aspects.

<1> A resin composition for molding, including:
a curable resin;
an inorganic filler, including one of silica particles and alumina particles, and calcium titanate particles.

A content ratio of the calcium titanate particles is 10% by volume or more and less than 30% by volume with respect to the entirety of the inorganic filler.

A content ratio of the entirety of the inorganic filler is more than 60% by volume with respect to the entirety of the resin composition for molding.

In the resin composition for molding according to <1>, the curable resin includes an epoxy resin, and the resin composition for molding further comprises a curing agent.

<3> In the resin composition for molding according to <2>, the curing agent includes an active ester compound.

<4> In the resin composition for molding according to <3>, the curing agent further includes a phenol curing agent.

<5> In the resin composition for molding according to any one of <2> to <4>, the epoxy resin includes at least one of an o-cresol novolac epoxy resin, a biphenyl aralkyl epoxy resin, and a biphenyl epoxy resin.

<6> In the resin composition for molding according to any one of <1> to <5>, the inorganic filler includes alumina particles.

<7> The resin composition for molding according to any one of <1> to <6> further includes a stress relaxation agent.

<8> In the resin composition for molding according to <7>, the stress relaxation agent includes at least one of an indene-styrene-coumarone copolymer and a triphenylphosphine oxide.

<9> In the resin composition for molding according to any one of <1> to <8>, a content ratio of a silicone-based stress relaxation agent is 5% by mass or less with respect to the entirety of the resin composition for molding.

<10> In the resin composition for molding according to <8>, the resin composition for molding does not include a silicone-based stress relaxation agent.

<11> In the resin composition for molding according to <1> to <10>, the resin composition for molding does not include titanium compound particles other than the calcium titanate particles.

<12> In the resin composition for molding according to in any one of <1> to <11>, the resin composition for molding is used in a high frequency device.

<13> In the resin composition for molding according to <12>, the resin composition for molding is used to seal an electronic component in the high frequency device.

<14> The resin composition for molding according to any one of <1> to <13>, the resin composition for molding is used in an antenna-in-package.

<15> An electronic component device includes:
a support member;
an electronic component, disposed on the support member; and
the resin composition for molding according to any one of <1> to <14>, sealing the electronic component.

<16> In the electronic component device according to <15>, the electronic component includes an antenna.

### Inventive Effects

According to the disclosure, a resin composition for molding able to mold a cured article having a low dielectric loss tangent while maintaining the relative dielectric constant and an electronic component device using the same are provided.

### DESCRIPTION OF EMBODIMENTS

In the disclosure, the term “process” includes not only processes that are independent from other processes but also those whose objectives are achieved even if such processes are not clearly distinguishable from other processes.

In the disclosure, the numerical ranges indicated by “˜” or “and” shall include the numerical values stated before and after “˜” or “and” as the minimum and maximum values, respectively.

In the numerical ranges described incrementally in this disclosure, the upper limit or lower limit described in one numerical range may be replaced by the upper limit or lower limit of another incrementally described numerical range. In addition, in the numerical ranges specified in the disclosure, the upper limit or lower limit of the numerical range may be replaced with the values indicated in the embodiments.

In the disclosure, each component may include multiple types of a corresponding substance. In the case where each component includes multiple types of the corresponding substance, the content ratio or the content quantity of each component, unless otherwise specified, refers to the total content ratio or content quantity of the multiple types of the substance present in the composition.

In the disclosure, each component may include multiple types of corresponding particles. In the case where each component includes multiple types of the corresponding particles, the particle size of each component, unless otherwise specified, refers to a value relating to the mixture of the corresponding multiple types of particles present in the composition.

In the disclosure, “total content ratio of silica particles and alumina particles” may be interpreted as “content ratio of silica particles” or “content ratio of alumina particles”.

In the disclosure, “total of silica particles and alumina particles” may be interpreted as “silica particles” or “alumina particles”.

In the following, the embodiments of the disclosure will be described in detail. However, the disclosure is not limited to the following embodiments. In the following embodiments, the constituent elements (including element steps, etc.) are not mandatory unless specifically stated otherwise. The disclosure is not limited to the values and ranges thereof in the following, either.

### <Resin Composition for Molding>

A resin composition for molding of the embodiment includes a curable resin, and an inorganic filler that includes at least one of silica particles and alumina particles, and calcium titanate particles. The content ratio of the calcium titanate particles is equal to or more than 10% by volume and less than 30% by volume with respect to the entirety of the inorganic filler. The content ratio of the entirety of the inorganic filler is more than 60% by volume with respect to the entirety of the resin composition for molding.

As described above, it is required to suppress the transmission loss in the cured article molded by using the resin composition for molding. From the perspective of suppressing transmission loss, it is desired to realize a low dielectric loss tangent. From the perspective of suppressing the transmission loss and miniaturizing the substrate as well as miniaturizing a semiconductor package, it is desired to suppress an excessive increase and decrease in the relative dielectric constant to set a balanced relative dielectric constant. In the resin composition for molding according to the embodiment, by combining at least one of the silica particles and the alumina particles with calcium titanate particles, making the content ratio of the calcium titanate particles equal to or more than 10% by volume and less than 30% by volume with respect to the entirety of the inorganic filler, and making the content ratio of the inorganic filler more than 60% by volume with respect to the entirety of the resin composition for molding, it is possible to mold a cured article having a low dielectric loss tangent while maintaining a relative dielectric constant suitable for suppressing the transmission loss, miniaturizing the substrate, and miniaturizing the semiconductor package.

In addition, in the resin composition for molding according to the embodiment, by using calcium titanate particles, it is possible to mold a cured article having a dielectric loss tangent lower than the case where barium titanate, etc., is used.

In the following, the respective components forming the resin composition for molding are described. The resin composition for molding of the embodiment includes a curable resin and an inorganic filler, and may include other components as necessary.

### (Curable Resin)

The resin composition for molding in the embodiment includes a curable resin.

The curable resin may be a thermosetting resin or a photocurable resin. From the perspective of mass productivity, a thermosetting resin is preferable.

Examples of the thermosetting resin may include epoxy resins, phenol resins, melamine resins, urea resins, unsaturated polyester resins, alkyd resins, urethane resins, polyimide resins such as bismaleimide resins, polyamide resins, polyamideimide resins, silicone resins, acrylic resins, etc.

From the perspective of moldability and electrical properties, the thermosetting resin is preferably at least one selected from the group consisting of epoxy resins and polyimide resins, more preferably at least one selected from the group consisting of epoxy resins and bismaleimide resins, and even more preferably an epoxy resin.

The resin composition for molding may include one type of curable resins only, and may also include two types of curable resins.

In the following, the epoxy resin is described as an example of the curable resin.

### —Epoxy Resin—

The resin composition for molding preferably includes an epoxy resin as the curable resin.

In the case where the resin composition for molding includes an epoxy resin as the curable resin, the content ratio of the epoxy resin with respect to the entirety of the curable resin is preferably 80% by mass or more, more preferably 90% by mass or more, and even more preferably 95% by mass or more. The content ratio of the epoxy resin with respect to the entirety of the curable resin may also be 100% by mass.

The type of the epoxy resin is not particularly limited as long as the epoxy resin has an epoxy group in the particles.

Specifically, as the epoxy resin, examples may include novolac epoxy resins (phenol novolac epoxy resins, o-cresol novolac epoxy resins, etc.) obtained by epoxidizing novolac resins obtained by condensing or co-condensing at least one phenol compound selected from the group consisting of a phenol compound such as phenol, cresol, xylenol, resorcin, catechol, bisphenol A, bisphenol F, etc., and a naphthol compound such as α-naphthol, β-naphthol, dihydroxynaphthalene, etc., and an aliphatic aldehyde compound such as formaldehyde, acetaldehyde, propionaldehyde, etc., in the presence of an acid catalyst; triphenylmethane epoxy resins obtained by epoxidizing a triphenylmethane phenol resin obtained by condensing or co-condensing the phenol compound and an aromatic aldehyde compound such as benzaldehyde or salicylaldehyde in the presence of an acid catalyst; copolymer epoxy resins obtained by epoxidizing a novolac resin obtained by co-condensing the phenol compound and naphthol compound with an aldehyde compound in the presence of an acid catalyst; diphenylmethane epoxy resins which are diglycidyl ethers of bisphenol A, bisphenol F, etc.; biphenyl epoxy resins which are diglycidyl ethers of alkyl-substituted or unsubstituted biphenols; stilbene-based epoxy resins which are diglycidyl ethers of stilbene-based phenol compounds; sulfur atom-containing epoxy resins which are diglycidyl ethers of bisphenol S or the like; epoxy resins that are glycidyl ethers of alcohols such as butanediol, polyethylene glycol, and polypropylene glycol; glycidyl ester epoxy resins, which are glycidyl esters of polycarboxylic acid compounds such as phthalic acid, isophthalic acid, and tetrahydrophthalic acid; glycidylamine epoxy resins in which active hydrogens bonded to nitrogen atoms of aniline, diaminodiphenylmethane, isocyanuric acid, etc. are substituted with a glycidyl group; dicyclopentadiene-type epoxy resins obtained by epoxidizing a co-condensation resin of dicyclopentadiene and a phenol compound; clicyclic epoxy resins such as vinylcyclohexene diepoxide, 3,4-epoxycyclohexylmethyl-3,4-epoxycyclohexanecarboxylate, and 2-(3,4-epoxy)cyclohexyl-5,5-spiro(3,4-epoxy)cyclohexane-m-dioxane, which are produced by epoxidizing olefin bonds in molecules; paraxylylene-modified epoxy resins which are glycidyl ethers of paraxylylene-modified phenolic resins; metaxylylene-modified epoxy resins, which are glycidyl ethers of metaxylylene-modified phenolic resins; terpene-modified epoxy resins which are glycidyl ethers of terpene-modified phenol resins; dicyclopentadiene-modified epoxy resins which are glycidyl ethers of dicyclopentadiene-modified phenolic resins; cyclopentadiene-modified epoxy resins which are glycidyl ethers of cyclopentadiene-modified phenolic resins; polycyclic aromatic ring-modified epoxy resins which are glycidyl ethers of polycyclic aromatic ring-modified phenol resins; naphthalene epoxy resins which are glycidyl ethers of naphthalene ring-containing phenolic resins; halogenated phenol novolac epoxy resins; hydroquinone epoxy resins; trimethylolpropane epoxy resins; linear aliphatic epoxy resins obtained by oxidizing olefin bonds with peracids such as peracetic acid; aralkyl epoxy resins obtained by epoxidizing aralkyl phenol resins such as phenol aralkyl resins and naphthol aralkyl resins, etc. Further examples of the epoxy resins include epoxidized products of acrylic resins. The epoxy resins may be used alone or in a combination of two or more types.

Regarding the epoxy resin, it is preferable that the epoxy resin includes at least one of the o-cresol novolac epoxy resin, the biphenyl aralkyl epoxy resin, and the biphenyl epoxy resin, and it is more preferable that the epoxy resin includes the o-cresol novolac epoxy resin and the biphenyl epoxy resin or the biphenyl aralkyl epoxy resin and the biphenyl epoxy resin.

The epoxy equivalent (molecular weight/number of epoxy groups) of the epoxy resin is not particularly limited. From the perspective of the balance among various properties, such as moldability, reflow resistance, and electrical reliability, the epoxy equivalent of the epoxy resin is preferably 100 g/eq to 1000 g/eq, more preferably 150 g/eq to 500 g/eq.

The epoxy equivalent of the epoxy resin is a value measured by using the method following JIS K 7236:2009.

If the epoxy resin is a solid, the softening point or melting point of the epoxy resin is not particularly limited. From the perspective of moldability and reflow resistance, the softening point or melting point of the epoxy resin is preferably 40° C. to 180° C., and from the perspective of the handling properties at the time of preparing the resin composition for molding, the softening point or melting point of the epoxy resin is more preferably 50° C. to 130° C.

The melting point or the softening point of the epoxy resin is a value measured according to differential scanning calorimetry (DSC) or a method (ring and ball method) following JIS K 7234:1986.

In the case where the resin composition for molding includes an epoxy resin as the curable resin, the mass ratio of the epoxy resin in the entirety of the resin composition for molding, from the perspective of strength, flowability, heat resistance, moldability, etc., is preferably 0.5% by mass to 30% by mass, more preferably 2% by mass to 20% by mass, and even more preferably 3.5% by mass to 13% by mass.

### —Curing Agent—

In the case where the resin composition for molding is an epoxy resin as the curable resin, the resin composition for molding may further include a curing agent. The resin composition for molding preferably includes the curable resin including the epoxy resin, the curing agent, and the inorganic filler that contains at least one of silica particles and alumina particles and calcium titanate particles. The type of the curing agent is not particularly limited.

The curing agent preferably includes an active ester compound. One type of the active ester compounds may be used alone or two or more types of the active ester compounds may be used in combination. Here, the active ester compound refers to a compound having, in one molecule, one or more ester groups reacting with an epoxy group and having a function of curing the epoxy resin. In the case where the curing agent includes the active ester compound, the curing agent may include or not include a curing agent other than the active ester compound.

When the active ester compound is used as the curing agent, the dielectric loss tangent of the cured article can be suppressed to be lower than the case where a phenol curing agent or an amine curing agent as the curing agent. The reasons are presumed as the following: The reaction between the epoxy resin and the phenol curing agent or the amine curing agent generates a secondary hydroxyl group. Comparatively, in the reaction between the epoxy resin and the active ester compound, an ester group is generated, instead of a secondary hydroxyl group.

The polarity of the ester group is lower than that of the secondary hydroxyl group. Therefore, compared with a resin composition for molding including, as the curing agent, only a curing agent that generates a secondary hydroxyl group, the resin composition for molding including the active ester compound as the curing agent can suppress the dielectric loss tangent of the cured article to be low.

In addition, while the polar group in the cured article facilitates the water absorption properties of the cured article, by using the active ester compound as the curing agent, the polar group concentration in the cured article can be suppressed, and the water absorption properties of the cured article can be suppressed. In addition, with the water absorption properties of the cured article being suppressed, that is, with the content quantity of H₂O as a polar molecule being suppressed, the dielectric loss tangent of the cured article can be suppressed to be even lower.

The type of the active ester compound is not particularly limited, as long as the compound has one or more ester group that reacts with the epoxy group in the molecule. As the active ester compound, examples may include esterified products of phenol ester compounds, thiophenol ester compounds, N-hydroxyamine ester compounds, heterocyclic hydroxyl compounds, etc.

As the active ester compound, examples may include ester compounds obtained from at least one of aliphatic carboxylic acids and aromatic carboxylic acids and at least one of aliphatic hydroxyl compounds and aromatic hydroxyl compounds. The ester compound that uses an aliphatic compound as a polycondensation component tends to exhibit excellent compatibility with epoxy resins due to the presence of an aliphatic chain. The ester compound that uses an aromatic compound as a polycondensation component tends to exhibit excellent heat resistance due to the presence of an aromatic ring.

As specific examples of the active ester compound, examples may include aromatic esters obtained by condensation reaction between aromatic carboxylic acids and phenol hydroxyl groups. Among these, aromatic esters obtained by condensation reaction between aromatic carboxylic acids and phenol hydroxyl groups by using, as raw materials, a mixture of an aromatic carboxylic acid component in which two to four hydrogen atoms of an aromatic ring, such as benzene, naphthalene, biphenyl, diphenylpropane, diphenylmethane, diphenyl ether, or diphenylsulfonic acid, are substituted with carboxyl groups, a monovalent phenol in which one hydrogen atom of the aromatic ring is substituted with a hydroxyl group; a polyvalent phenol in which two to four hydrogen atoms of the aromatic ring is substituted with a hydroxyl group; are preferred. That is, an aromatic ester having a structural unit derived from the aromatic carboxylic acid component, a structural unit derived from the monovalent phenol, and a structural unit derived from the polyvalent phenol is preferred.

As a specific example of the active ester compound, Japanese Laid-open No. 2012-246367 discloses, for example, a phenol resin having a molecular structure in which a phenolic compound is bonded via an alicyclic hydrocarbon group; and an active ester resin having a structure obtained by reacting an aromatic dicarboxylic acid or its halide with an aromatic monohydroxyl compound. As the active ester resin, a compound represented in Structural Formula (1) as follows is preferred.

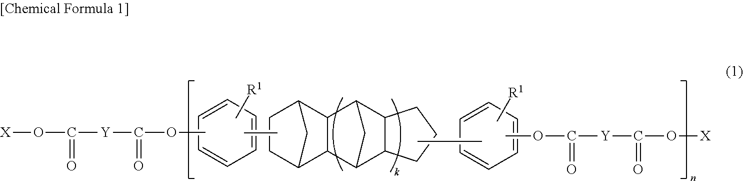

In Structural Formula (1), R1 is a hydrogen atom, an alkyl group or a phenyl group having a carbon number of 1 to 4, X is an unsubstituted benzene ring, an unsubstituted naphthalene ring, a benzene ring or a naphthalene ring substituted with an alkyl group having a carbon number of 1 to 4, or a biphenyl group, Y is a benzene ring, a naphthalene ring, or a benzene ring or a naphthalene ring substituted with an alkyl group having a carbon number of 1 to 4, k is 0 or 1, n is an averaged repetition number and is 0 to 5.

As a specific example of the compound represented by Structural Formula (1), examples may include compounds (1-1) to (1-10) below. “t-Bu” in the structural formula is a tert-butyl group.

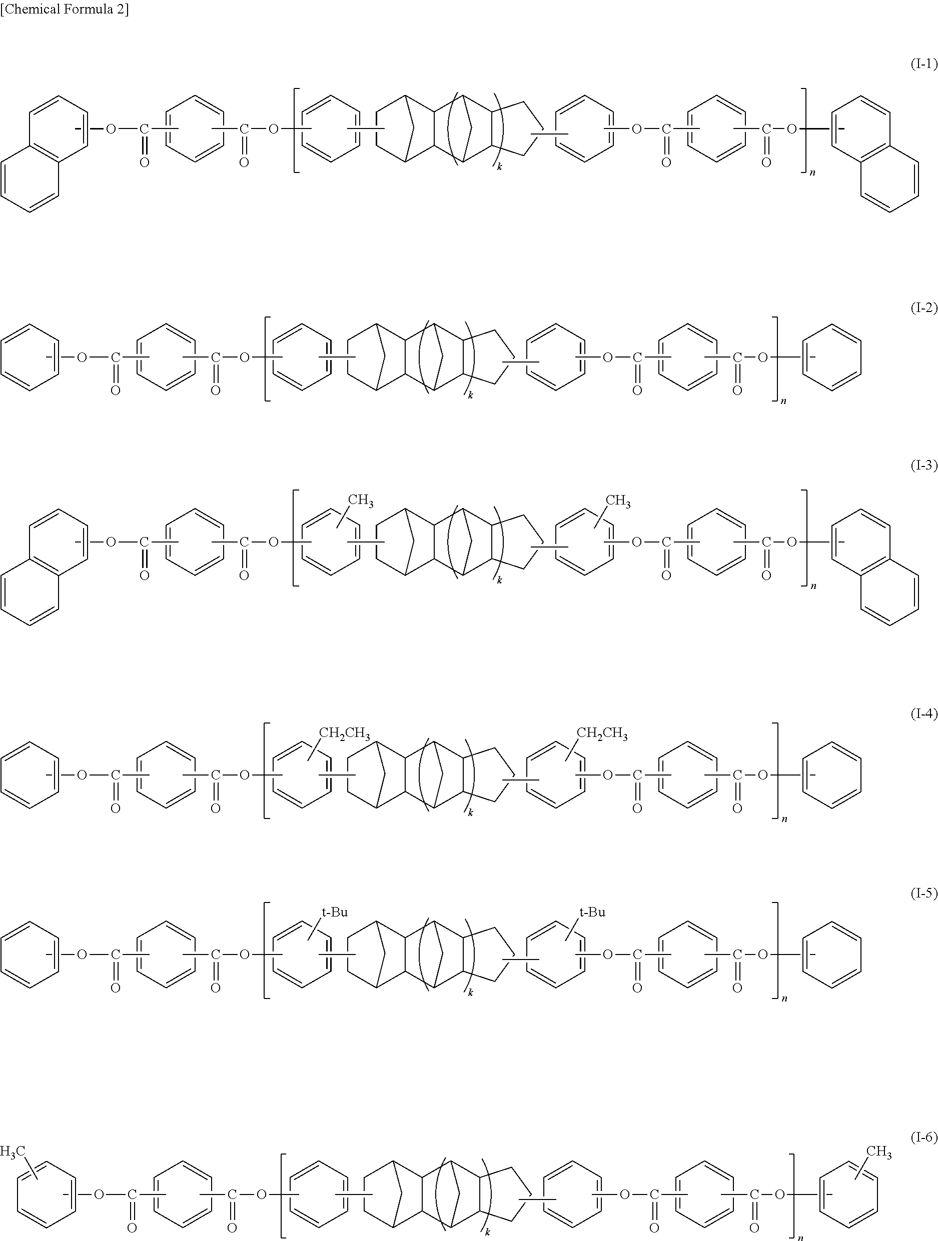

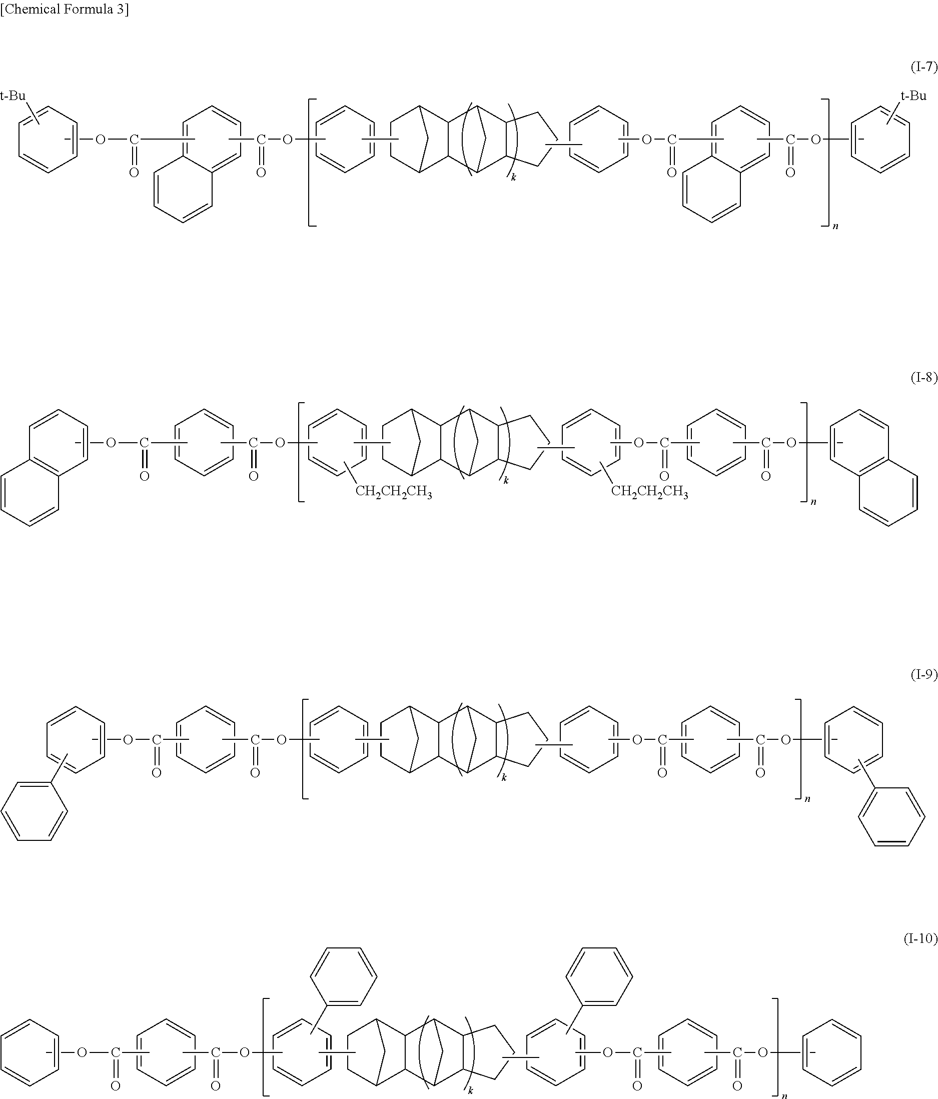

As another specific example of the active ester compound, Japanese Laid-open No. 2014-114352 discloses, for example, a compound represented by Structural Formula (2) below and a compound represented by Structural Formula (3).

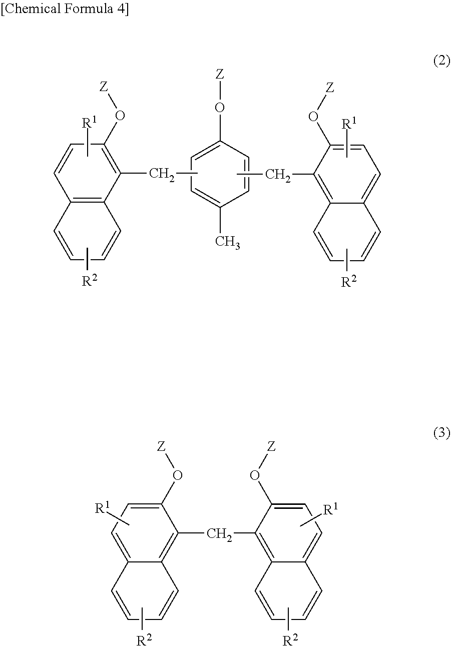

In Structural Formula (2), R1 and R2 are each independently a hydrogen atom, an alkyl group having a carbon number of 1 to 4, or an alkoxy group having a carbon number of 1 to 4, Z is an ester-forming structural unit (z1) selected from the group consisting of an unsubstituted benzoyl group, an unsubstituted naphthoyl group, a benzoyl group or a naphthoyl group substituted with an alkyl group having a carbon number of 1 to 4, and an acyl group having a carbon number of 2 to 6 or a hydrogen atom (z2), and at least one of Z is the ester forming structural unit (z1).

In Structural Formula (3), R1 and R2 are each independently a hydrogen atom, an alkyl group having a carbon number of 1 to 4, or an alkoxy group having a carbon number of 1 to 4, Z is an ester-forming structural unit (z1) selected from the group consisting of an unsubstituted benzoyl group, an unsubstituted naphthoyl group, a benzoyl group or a naphthoyl group substituted with an alkyl group having a carbon number of 1 to 4, and an acyl group having a carbon number of 2 to 6 or a hydrogen atom (z2), and at least one of Z is the ester forming structural unit (z1).

As specific examples of the compound represented by Structural Formula (2), examples may include compounds (2-1) to (2-6) below.

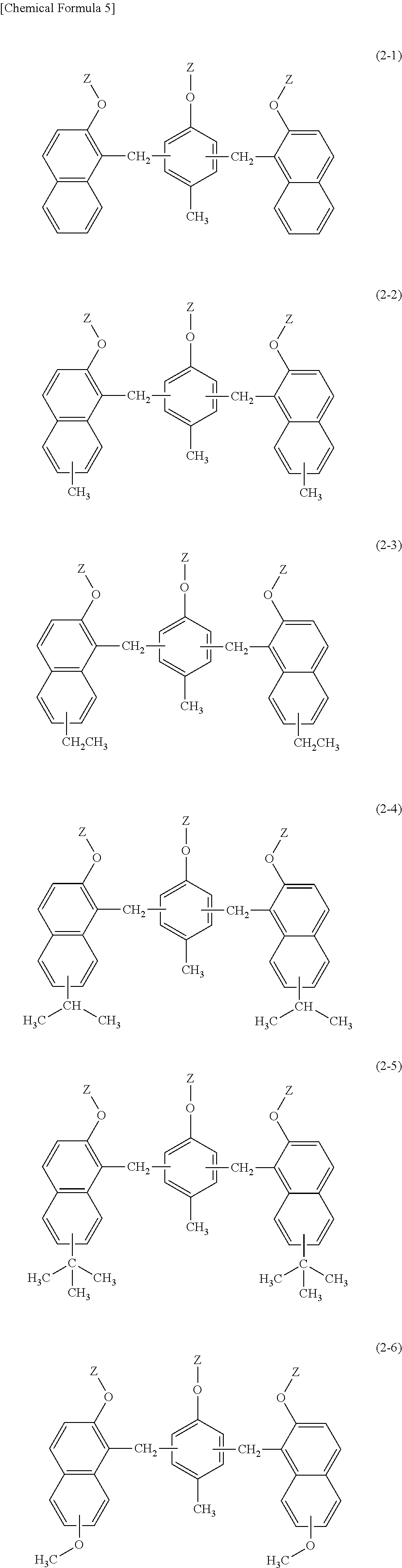

As specific examples of the compound represented by Structural Formula (3), examples may include compounds (3-1) to (3-6) below.

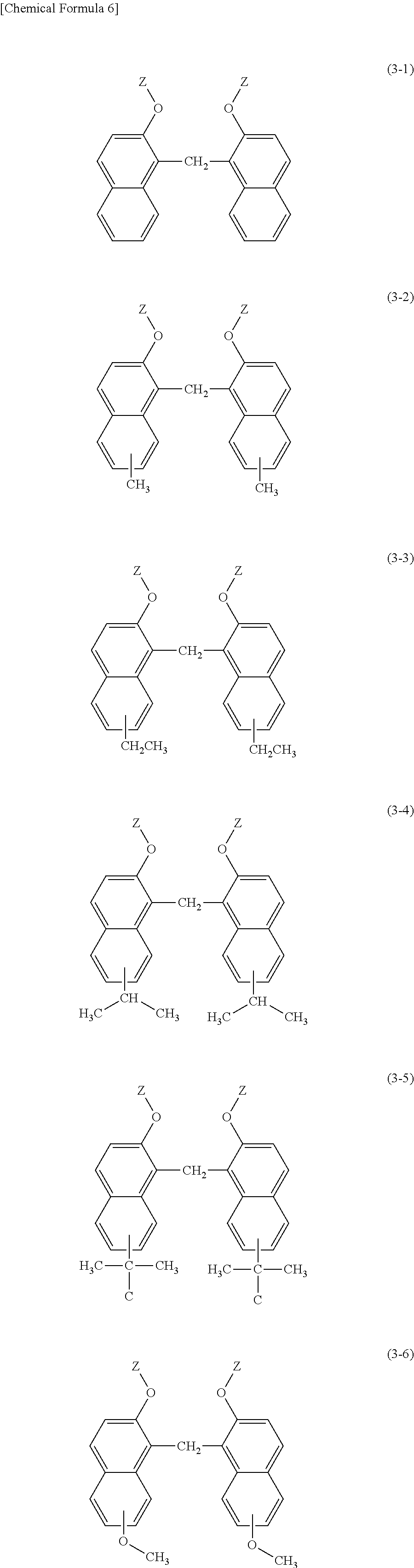

As the active ester compound, commercially available products may be used. As the commercially available products of the active ester compound, examples may include: “EXB9451”, “EXB9460”, “EXB9460S”, and “HPC-8000-65T” (manufactured by DIC Corporation) as active ester compounds including a dicyclopentadiene diphenol structure; “EXB9416-70BK”, “EXB-8”, and “EXB-9425” (manufactured by DIC Corporation) as active ester compounds including an aromatic structure; “DC808” (manufactured by Mitsubishi Chemical Corporation) as an active ester compound containing an acetylatedphenol novolac product; and “YLH1026” (manufactured by Mitsubishi Chemical Corporation) as an active ester compound containing a benzoylated phenol novolac product, etc.

The ester equivalent (molecular weight/number of ester groups) of the active ester compound is not particularly limited. From the perspective of the balance among various properties, such as moldability, reflow resistance, and electrical reliability, the ester equivalent is preferably 150 g/eq to 400 g/eq, more preferably 170 g/eq to 300 g/eq, and even more preferably 200 g/eq to 250 g/eq.

The ester equivalent of the active ester compound is a value measured by using the method following JIS K 0070:1992.

From the perspective of suppressing the dielectric loss tangent of the cured article to be low, the equivalent ratio (ester group/epoxy group) between the epoxy resin and the active ester compound is preferably 0.9 or more, more preferably 0.95 or more, and even more preferably 0.97 or more.

From the perspective of suppressing the unreacted portion of the active ester compound, the equivalent ratio (ester group/epoxy group) between the epoxy resin and the active ester compound is preferably 1.1 or less, more preferably 1.05 or less, and even more preferably 1.03 or less.

The curing agent may also include a curing agent other than the active ester compound. The type of such other curing agents is not particularly limited, and can be selected in accordance with the desired properties, etc., of the resin composition for molding. Example of such other curing agents may include a phenol curing agent, an amine curing agent, an acid anhydride curing agent, a polymercaptan curing agent, a polyaminoamide curing agent, an isocyanate curing agent, a blocked isocyanate curing agent, etc.

Specifically, as the phenol curing agent, examples may include: a polyvalent phenol compounds such as resorcin, catechol, bisphenol A, bisphenol F, and substituted or unsubstituted biphenol; novolac phenolic resins obtained by condensing or co-condensing, under the an acid catalyst, at least one phenol compound selected from the group consisting of a phenol compound such as phenol, cresol, xylenol, resorcin, catechol, bisphenol A, bisphenol F, phenylphenol, aminophenol, etc., and a naphthol compound such as α-naphthol, β-naphthol, dihydroxynaphthalene, etc., with an aldehyde compound such as formaldehyde, acetaldehyde, propionaldehyde, etc.; aralkyl phenol resins such as phenol aralkyl resins and naphthol aralkyl resins synthesized from the phenol compound and dimethoxy-para-xylene, bis(methoxymethyl) biphenyl, etc.; paraxylylene modified phenol resins, metaxylylene modified phenol resins; melamine modified phenol resins; terpene modified phenolic resins;

dicyclopentadiene-type phenol resins and dicyclopentadiene-type naphthol resins synthesized by copolymerizing the phenol compound with dicyclopentadiene; cyclopentadiene modified phenolic resins; polycyclic aromatic ring modified phenol resins; biphenyl phenol resins; triphenylmethane phenol resins obtained by condensing or co-condensing the phenol compound and an aromatic aldehyde compound such as benzaldehyde or salicylaldehyde in the presence of an acid catalyst; phenol resins obtained by copolymerizing two or more of the above. The phenol curing agents may be used alone or in a combination of two or more types.

The functional group equivalent of other curing agents (the hydroxyl group equivalent in the case of a phenol curing agent) is not particularly limited. From the perspective of the balance among various properties, such as moldability, reflow resistance, and electrical reliability, the functional group equivalent of other curing agents is preferably 70 g/eq to 1000 g/eq, and more preferably 80 g/eq to 500 g/eq.

The functional group equivalent of other curing agents (the hydroxyl group equivalent in the case of a phenol curing agent) is a value measured by using the method following JIS K 0070:1992.

The softening point or the melting point of the curing agent is not particularly limited. From the perspective of moldability and reflow resistance, the softening point or melting point of the curing agent is preferably 40° C. to 180° C., and from the perspective of the handling properties at the time of manufacturing the resin composition for molding, the softening point or melting point of the curing agent is more preferably 50° C. to 130° C.

The melting point or the softening point of the curing agent is set to be a value measured in the same way as that of the melting point or the softening point of the epoxy resin.

The equivalent ratio between the epoxy resin and the curing agent (all of the curing agents in the case where multiple types of curing agents are used), that is, the functional group number ratio of the curing agent with respect to the functional group number in the epoxy resin (the functional group number in the curing agent/the functional group number in the epoxy resin), is not particularly limited. From the perspective of suppressing the unreacted portion of each, it is preferable to set a range of 0.5 to 2.0, and more preferably to set a range of 0.6 to 1.3. From the perspective of moldability and reflow resistance, it is preferable to set a range of 0.8 to 1.2.

The curing agent may include the active ester compound and at least one other curing agent selected from the group consisting of phenol curing agents, amine curing agents, acid anhydride curing agents, polymercaptan curing agents, polyaminoamide curing agents, isocyanate curing agents, and block isocyanate curing agents. From the perspective of having excellent bending toughness after the resin composition for molding is cured, the curing agent may include a phenol curing agent and the active ester compound, may include an aralkyl phenol resin and the active ester compound, or may include an aralkyl phenol resin, a melamine-modified phenolic resin, and the active ester compound.

In the following, such other curing agent may be interpreted as a phenol curing agent.

In the case where the curing agent includes the active ester compound and the other curing agent, from the perspective of suppressing the dielectric loss tangent of the cured article to be low, the mass ratio of the active ester compound in the total amount of the active ester compound and the other curing agent is preferably 40% by mass or more, more preferably 60% by mass, even more preferably 80% by mass or more, particularly preferably 85% by mass or more, and highly preferably 90% by mass or more.

In the case where the curing agent includes the active ester compound and the other curing agent, from the perspective of suppressing the dielectric loss tangent of the cured article to be low, the total mass ratio of the epoxy resin and the active ester compound in the total amount of the epoxy resin and the curing agent is preferably 40% by mass or more, more preferably 60% by mass, even more preferably 80% by mass or more, particularly preferably 85% by mass or more, and highly preferably 90% by mass or more.

In the case where the curing agent includes the active ester compound and the other curing agent, from the perspective of having excellent bending toughness after the resin composition for molding is cured, the mass ratio of the active ester compound in the total amount of the active ester compound and the other curing agent is preferably 40% by mass to 90% by mass, more preferably 50% by mass to 80% by mass, particularly preferably 55% by mass to 70% by mass.

In the case where the curing agent includes the active ester compound and the other curing agent, from the perspective of having excellent bending toughness after the resin composition for molding is cured and the perspective of suppressing the dielectric loss tangent of the cured article to be low, the mass ratio of the other curing agent in the total amount of the active ester compound and the other curing agent is preferably 10% by mass to 60% by mass, more preferably 20% by mass to 50% by mass, and even more preferably 30% by mass to 45% by mass.

In the case where the resin composition for molding includes the epoxy resin and the curing agent, the content ratio of the curable resin other than the epoxy resin may be, with respect to the entirety of the resin composition for molding, less than 5% by mass, less than 4% by mass, or less than 3% by mass.

### —Polyimide Resin—

The resin composition for molding may also include a polyimide resin as the curable resin. The polyimide resin is not particularly limited as long as it is a polymer compound having an imide bond. As the polyimide resin, examples may include bismaleimide resins.

As the bismaleimide resin, examples may include copolymers of a compound having two or more N-substituted maleimide groups and a compound having two or more amino groups. In the following, the compound having two or more N-substituted maleimide groups may also be referred to as a “polymaleimide compound”, and the compound having two or more amino groups may also be referred to as a “polyamino compound”.

It is not particularly limited as long as the bismaleimide resin is a polymer in which a composition including the polymaleimide compound and the polyamino compound is polymerized, and may include a unit derived from a compound other than the polymaleimide compound and the polyamino compound. As the other compound, examples may include compounds having a group containing two or more ethylenically unsaturated double bonds. In the following, the compound having a group containing two or more ethylenically unsaturated double bonds may also be referred to as an “ethylene compound”.

It is not particularly limited as long as the polymaleimide compound is a compound having two or more N-substituted maleimide groups. The polymaleimide compound may be a compound having two N-substituted maleimide groups, and may also be a compound having three or more N-substituted maleimide groups. From the perspective of availability, the polymaleimide compound is preferably a compound having two N-substituted maleimide groups.

As specific examples of the polymaleimide compound, examples may include: bis(4-maleimidophenyl) methane, bis(3-maleimidophenyl) methane, polyphenylmethane maleimide, bis(4-maleimidophenyl) ether, bis(4-maleimidophenyl) sulfone, 3,3′-dimethyl-5,5′-diethyl-4,4′-diphenylmethane bismaleimide, 4-methyl-1,3-phenylene bismaleimide, m-phenylene bismaleimide, p-phenylene bismaleimide, 2,2-bis[4-(4-maleimidophenoxy)phenyl]propane, 1,2-bismaleimidoethane, 1,6-bismaleimidohexane,1,12-bismaleimidododecane, 1,6-bismaleimido-(2,2,4-trimethyl) hexane, 1,6-bismaleimido-(2,4,4-trimethyl) hexane, etc.

The polymaleimide compounds may be used alone or in a combination of two or more types.

It is not particularly limited as long as the polyamino compound is a compound having two or more amino groups. The polyamino compound may be a compound having two amino groups, and may also be a compound having three or more amino groups. From the perspective of availability, the polyamino compound is preferably a compound having two amino groups.

As specific examples of the polyamino compound, examples may include: 4,4′-diaminodiphenylmethane, 4,4′-diamino-3,3′-dimethyl-diphenylmethane, 4,4′-diamino-3,3′-diethyl-diphenylmethane, 4,4′-diaminodiphenyl ether, 4,4′-diaminodiphenyl sulfone, 3,3′-diaminodiphenyl sulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl) propane, 3,3′-dimethyl-5,5′-diethyl-4,4′-diphenylmethanediamine, 2,2-bis(4-aminophenyl) propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy) biphenyl, 1,3-bis[1-(4-(4-aminophenoxy)phenyl)-1-methylethyl]benzene, 1,4-bis[1-(4-(4-aminophenoxy)phenyl)-1-methylethyl]benzene, 4,4′-[1,3-phenylenebis(1-methylethylidene)]bisaniline, 4,4′-[1,4-phenylenebis(1-methylethylidene)]bisaniline, 3,3′-[1,3-phenylenebis(1-methylethylidene)]bisaniline, bis[4-(4-aminophenoxy)phenyl]sulfone, bis[4-(3-aminophenoxy)phenyl]sulfone, 9,9-bis(4-aminophenyl) fluorene, etc.

The polyamino compounds may be used alone or in a combination of two or more types.

Examples of the “group containing an ethylenically unsaturated double bond” in the ethylene compound include a vinyl group, an allyl group, a vinyloxy group, an allyloxy group, an acryloyl group, and a methacryloyl group, etc. The ethylene compound may include only one type of group including an ethylenically unsaturated double bond, and may also include two or more types thereof.

In addition to the ethylenically unsaturated double bond, the ethylene compound may further have other groups. As such other groups, examples may include an amino group, an ether group, a sulfide group, etc.

As specific examples of the ethylene compound, examples may include diallyl amine, diallyl ether, diallyl sulfide, triallyl isocyanurate, etc.

In the bismaleimide resin, the equivalent ratio (Ta1/Ta2) of the number (Ta1) of N-substituted maleimide group in the polymaleimide compound with respect to the number of amino group (Ta2) in the polyamino compound is preferably in a range of 1.0 to 10.0, and more preferably in a range of 2.0 to 10.0.

In addition, in the case where the bismaleimide resin includes a unit derived from the ethylene compound, as an equivalent ratio (Ta3/Ta1) of the number (Ta3) of ethylenically unsaturated double bond with respect to the number (Ta1) of N-substituted maleimide group of the polymaleimide compound in the bismaleimide resin, examples include a range of 0.05 to 0.2.

The weight average molecular weight of the bismaleimide resin is not particularly limited, and may be, for example, in a range of 800 to 1500, may also be a range of 800 to 1300, and may also be a range of 800 to 1100.

The weight average molecular weight of the bismaleimide resin can be obtained through the conversion from a calibration curve using standard polystyrene by using gel permeation chromatography (GPC).

The calibration curve is approximated by using a cubic equation using the standard polystyrene: TSK standard POLYSTYRENE (Type: A-2500, A-5000, F-1, F-2, F-4, F-10, F-20, F-40), [manufactured by Tosoh Corporation].

As the devices used in GPC, examples may include: pump: L-6200 (Hitachi High-Technologies Corporation); detector: L-3300 RI (Hitachi High-Technologies Corporation); column oven: L-655A-52 (Hitachi High-Technologies Corporation); guard column: TSK Guardcolumn HHR-L (Tosoh Corporation, column size 6.0 mm×40 mm); column: TSK gel-G4000HHR+gel-G2000HHR (Tosoh Corporation, column size 7.8 mm×300 mm).

As the GPC measurement conditions, examples may include: eluent: tetrahydrofuran; sample concentration: 30 mg/5 mL; injection amount: 20 μL; flow rate: 1.00 mL/min; measurement temperature: 40° C.

In the case where the resin composition for molding includes a polyimide resin as the curable resin, the mass ratio of the polyimide resin in the entirety of the resin composition for molding may be, for example, 0.5% by mass to 30% by mass, preferably 2% by mass to 20% by mass, more preferably 3.5% by mass to 13% by mass.

### (Curing Accelerator)

The resin composition for molding in the embodiment may also include a curing accelerator as needed. The type of the curing accelerator is not particularly limited, and can be selected in accordance with the type of the curable resin, the desired properties of the resin composition for molding, etc.

As the curing accelerator used in the resin composition for molding containing at least one selected from the group consisting of an epoxy resin and a polyimide resin as a curable resin, examples may include: diazabicycloalkenes like 1,5-diazabicyclo[4.3.0]nonene-5 (DBN), 1,8-diazabicyclo[5.4.0]undecene-7 (DBU), etc., cyclic amidine compounds like 2-methylimidazole, 2-phenylimidazole, 2-phenyl-4-methylimidazole, 2-ethyl-4-methylimidazole, 2-heptadecylimidazole, etc.; derivatives of the cyclic amidine compound; phenol novolac salts of the cyclic amidine compound or the derivatives thereof; compounds having intramolecular polarization obtained by adding a compound having a π bond, such as maleic anhydride, a quinone compound like, 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, and phenyl-1,4-benzoquinone, and diazophenylmethane, to the compounds; cyclic amidinium compounds such as tetraphenylborate salts of DBU, tetraphenylborate salts of DBN, tetraphenylborate salts of 2-ethyl-4-methylimidazole, and tetraphenylborate salts of N-methylmorpholine; tertiary amine compounds such as pyridine, triethylamine, triethylenediamine, benzyldimethylamine, triethanolamine, dimethylaminoethanol, and tris(dimethylaminomethyl) phenol; derivatives of the tertiary amine compound; ammonium salt compounds such as tetra-n-butylammonium acetate, tetra-n-butylammonium phosphate, tetraethylammonium acetate, tetra-n-hexylammonium benzoate, and tetrapropylammonium hydroxide; organic phosphines, such as primary phosphines like ethylphosphine and phenylphosphine; secondary phosphines like dimethylphosphine and diphenylphosphine; tertiary phosphines such as triphenylphosphine, diphenyl(p-tolyl)phosphine, tris(alkylphenyl)phosphine, tris(alkoxyphenyl)phosphine, tris(alkyl/alkoxyphenyl)phosphine, tris(dialkylphenyl)phosphine, tris(trialkylphenyl)phosphine, tris(tetraalkylphenyl)phosphine, tris(dialkoxyphenyl)phosphine, tris(trialkoxyphenyl)phosphine, tris(tetraalkoxyphenyl)phosphine, trialkylphosphine, dialkylarylphosphine, alkyldiarylphosphine, trinaphthylphosphine, and tris(benzyl)phosphine; phosphine compounds such as complexes of the organic phosphines and organic borons; compounds having intramolecular polarization obtained by adding a compound having a π bond, such as maleic anhydride, a quinone compound like 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, phenyl-1,4-benzoquinone, and anthraquinone, and diazophenylmethane, etc., to the organic phosphine or the phosphine compound; compounds having intramolecular polarization obtained by reacting the organic phosphine or the phosphine compound with a halogenated phenol compound, such as 4-bromophenol, 3-bromophenol, 2-bromophenol, 4-chlorophenol, 3-chlorophenol, 2-chlorophenol, 4-iodophenol, 3-iodophenol, 2-iodophenol, 4-bromo-2-methylphenol, 4-bromo-3-methylphenol, 4-bromo-2,6-dimethylphenol, 4-bromo-3,5-dimethylphenol, 4-bromo-2,6-di-tert-butylphenol, 4-chloro-1-naphthol, 1-bromo-2-naphthol, 6-bromo-2-naphthol, 4-bromo-4′-hydroxybiphenyl, etc., and then subjecting the reacted compound to a dehydrohalogenation step; tetra-substituted phosphonium compounds, such as tetra-substituted phosphonium like tetraphenylphosphonium, tetraphenylborate salts of tetra-substituted phosphonium like tetraphenylphosphonium tetra-p-tolylborate, and salts of tetra-substituted phosphonium with phenol compounds; salts of tetraalkylphosphonium and partial hydrolysates of aromatic carboxylic acid anhydrides; phosphobetaine compounds; adducts of phosphonium compounds and silane compounds.

One type of the curing accelerator may be used alone or two or more types of the curing accelerators may be used in combination.

Among the curing accelerators, a curing accelerator including organic phosphine is preferred. As the curing accelerator including organic phosphine, examples may include the organic phosphine; a phosphine compound such as a complex of the organic phosphine and an organic boron; a compound having intramolecular polarization formed by adding a compound having a π bond to the organic phosphine or the phosphine compound.

As a particularly preferable curing accelerator among the above, examples may include triphenylphosphine, adducts of triphenylphosphine and quinone compounds, adducts of tributylphosphine and quinone compounds, adducts of tri-p-tolylphosphine and quinone compounds, etc.

In the case where the resin composition for molding includes a curing accelerator, the amount of the curing accelerator is preferably 0.1 parts by mass to 30 parts by mass, and more preferably 1 part by mass to 15 parts by mass, with respect to 100 parts by mass of the resin component. When the amount of the curing accelerator is 0.1 parts by mass or more with respect to 100 parts by mass of the resin component, there is a tendency that the composition cures favorably within a short time. When the amount of the curing accelerator is 30 parts by mass or less with respect to 100 parts by mass of the resin component, there is a tendency that a favorable molded article can be obtained without an excessively fast curing speed.

Here, the resin component refers to the curable resin and the curing agent used as necessary. In addition, 100 parts by mass of the resin component means that the total amount of the curable resin and the curing agent used as necessary is 100 parts by mass.

### (Curing Initiator)

In the case where the resin composition for molding includes the polyimide resin as the curable resin, the resin composition for molding may also include a curing initiator as needed.

As the curing initiator, examples may include a radial polymerization initiator, etc., that generates free radial radials by heating. As the curing initiator, specific examples may include inorganic peroxides, organic peroxides, azo compounds, etc.

As the inorganic peroxides, examples may include potassium persulfate (dipotassium peroxosulfate), sodium persulfate, ammonium persulfate, etc.

Examples of the organic peroxides may include: ketone peroxides such as methyl ethyl ketone peroxide, cyclohexanone peroxide; peroxyketals, such as 1,1-di(t-butylperoxy)cyclohexane, 2,2-di(4,4-di(t-butylperoxy)cyclohexyl) propane; hydroperoxides such as p-menthane hydroperoxide, diisopropylbenzene hydroperoxide, 1,1,3,3-tetramethylbutyl hydroperoxide, cumene hydroperoxide, and t-butyl hydroperoxide; dialkyl peroxides such as α,α′-di(t-butylperoxy) diisopropylbenzene, dicumyl peroxide, 2,5-dimethyl-2,5-di(t-butylperoxy) hexane, t-butylcumyl peroxide, di-t-hexyl peroxide, 2,5-dimethyl-2,5-di(t-butylperoxy) hexyne-3, and di-t-butyl peroxide; diacyl peroxides such as dibenzoyl peroxide and di(4-methylbenzoyl) peroxide; peroxydicarbonates such as di-n-propyl peroxydicarbonate and diisopropyl peroxydicarbonate; peroxy esters such as 2,5-dimethyl-2,5-di(benzoylperoxy) hexane, t-hexyl peroxybenzoate, t-butyl peroxybenzoate, and t-butyl peroxy 2-ethylhexanoate, etc.

As the azo compounds, examples may include: azobisisobutyronitrile, azobis-4-methoxy-2,4-dimethylvaleronitrile, azobiscyclohexane-1-carbonitrile, azodibenzoyl, etc.

In the case where the resin composition for molding includes a curing initiator, from the perspective of curability, the content amount of the curing initiator is preferably 0.1 parts by mass to 8.0 parts by mass, and more preferably 0.5 parts by mass to 6.0 parts by mass, with respect to 100 parts by mass of the polyimide compound. When the content amount of the curing initiator is 8.0 parts by mass or less, volatile matter is less likely to be generated, and voids during curing tend not to be generated. In addition, by setting the content of the curing initiator to 1 part by mass or more, the curability tends to be better.

### (Inorganic Filler)

The resin composition for molding of the embodiment includes an inorganic filler that includes at least one of silica particles and alumina particles, as well as calcium titanate particles.

The inorganic filler may also include fillers other than silica particles, alumina particles, or calcium titanate particles.

### —At Least One of Silica Particles and Alumina Particles—

The inorganic filler includes at least one of the silica particles and the alumina particles. The inorganic filler may include only one or both of the silica particles and alumina particles.

The silica particles and the alumina particles may each independently be used alone or in combination of two or more types. The silica particles and alumina particles may also be a mixture of two or more types of fillers having different volume average particle sizes.

The silica particles are not particularly limited, and examples may include fused silica, crystalline silica, and glass. The shape of the silica particles is not particularly limited, and examples thereof may include spherical, elliptical, and irregular shapes. The silica particles may be crushed.

The silica particles may be subjected to surface processing.

The shape of the alumina particles is not particularly limited, and examples thereof may include spherical, elliptical, and irregular shapes. The alumina particles may be crushed.

The alumina particles may be subjected to surface processing.

From the perspective of dielectric constant and thermal conductivity, the inorganic filler preferably include alumina particles.

The total content ratio of the silica particles and the alumina particles is preferably more than 70% by volume and equal to or less than 95% by volume, more preferably 75% by volume to 90% by volume, and even more preferably 75% by volume to 85% by volume, with respect to the entirety of the inorganic filler.

The content ratio (% by volume) of the silica particles, the content ratio (% by volume) of the alumina particles, and the content ratio (% by volume) of the calcium titanate particles, with respect to the entirety of the inorganic filler, can be calculated according to the following method. A thin sheet sample of the cured article of the resin composition for molding is photographed with a scanning electron microscope (SEM). An arbitrary area S is specified in the SEM image, and a total area A of the inorganic filler included in the area S is calculated. The total area B of specific particles such as the silica particles, the alumina particles, the calcium titanate particles, etc., included in the total area A of the inorganic filler is calculated by identifying the element of the inorganic filler by using energy dispersive X-ray spectrometry (SEM-EDX). The value obtained by dividing the total area B of the specific particles by the total area A of the inorganic filler is converted into a percentage (%), and the value is defined as the content ratio (volume %) of the specific particles with respect to the entirety of the inorganic filler.

The area S is set to be sufficiently large relative to the size of the inorganic filler. For example, the area is set to include 100 or more inorganic fillers 100. The area S may be the total of multiple cut surfaces.

In the case where the inorganic filler includes the silica particles and the alumina particles, alumina particle: silica particle, which is the volume ratio between the alumina particles and the silica particles, may be 10:90 to 90:10, may also be 30:70 to 90:10, may also be 50:50 to 90:10, and may also be 70:30 to 90:10.

The total content ratio of the silica particles and the alumina particles, from the perspective of low dielectric loss tangent, is preferably 30% by volume to 85% by volume, more preferably 35% by volume to 80% by volume, and even more preferably 40% by volume 75% by volume, with respect to the entirety of the resin composition for molding.

In the resin composition for molding, from the perspective of the balance between the dielectric loss tangent and the flowability, the mass ratio of the total of the silica particles and the alumina particles with respect to the total of the epoxy resin and the curing agent (the total of the silica particles and the alumina particles/the total of the epoxy resin and the curing agent) is preferably 1 to 25, more preferably 2 to 20, even more preferably 3 to 15, and particularly preferably 4 to 12.

The volume average particle size of the silica particles and the volume average particle size of the alumina particles are not particularly limited. The volume average particle size of the silica particles and the volume average particle size of the alumina particles are, respectively independently, preferably 0.2 μm to 100 μm, and more preferably 0.5 μm to 50 μm. When the volume average particle size is 0.2 μm or more, the increase in the viscosity of the resin composition for molding tends to be further suppressed. When the volume average particle size is 100 μm or less, the fillability of the resin composition for molding tends to be further increased. Regarding the volume average particle size of the silica particles and the volume average particle size of the alumina particles, the resin composition for molding is placed in a crucible and left at 800° C. for 4 hours to be incinerated. The obtained ash is observed by the SEM and separated by shape, and the particle size distribution is obtained from the observed image. From the particle size distribution, the volume average particle size of the silica particles and the volume average particle size of the alumina particles can be obtained as the volume average particle size (D50). In addition, the volume average particle size of the silica particles and the volume average particle size of the alumina particles may also be obtained through measurement by using a laser diffraction/scattering particle size distribution measurement device (e.g., HORIBA, Ltd., LA920).

The volume average particle size of the silica particles and the volume average particle size of the alumina particles may be, from the perspective of the viscosity of the resin composition for molding, respectively and independently 3 μm or more or 5 μm or more, and, from the perspective of the flowability of the resin composition for molding, respectively and independently 10 μm or more or 20 μm or more.

### —Calcium Titanate Particles—

The shape of the calcium titanate particles is not particularly limited, and examples thereof may include spherical, elliptical, and irregular shapes. The calcium titanate particles may be crushed. The calcium titanate particles may be subjected to surface processing.

The calcium titanate particles may also be a mixture of two or more types of fillers having different volume average particle sizes.

The volume average particle size of the calcium titanate particles is preferably 0.1 μm to 100 μm, more preferably 0.2 μm to 80 μm, even more preferably 0.5 μm to 30 μm, particularly preferably 0.5 μm to 10 μm, and highly preferably 0.5 μm to 8 μm.

The volume average particle size of the calcium titanate particles can be measured according to the following. The resin composition for molding is placed in a crucible and left at 800° C. for 4 hours to be incinerated. The obtained ash is observed by the SEM and separated by shape, and the particle size distribution is obtained from the observed image. From the particle size distribution, the volume average particle size of the calcium titanate particles can be obtained as the volume average particle size (D50). In addition, the volume average particle size of the calcium titanate particles may also be obtained through measurement by using a laser diffraction/scattering particle size distribution measurement device (e.g., HORIBA, Ltd., LA920).

The content ratio of the calcium titanate particles, from the perspective of the balance between the dielectric constant and the dielectric loss tangent, is 10% by volume or more and less than 30% by volume, preferably 15% by volume to 25% by volume, and more preferably 20% by volume to 25% by volume, with respect to the entirety of the inorganic filler.

The content ratio of the calcium titanate particles, from the perspective of the balance between the dielectric constant and the dielectric loss tangent, is preferably 5% by volume to 30% by volume, more preferably 7% by volume to 25% by volume, and even more preferably 10% by volume to 20% by volume, with respect to the entirety of the resin composition for molding.

In the resin composition for molding, from the perspective of the balance between the dielectric loss tangent and the flowability, the mass ratio of the calcium titanate particles with respect to the total of the epoxy resin and the curing agent (the calcium titanate particles/the total of the epoxy resin and the curing agent) is preferably 1 to 10, more preferably 1.2 to 8, even more preferably 1.5 to 6, and particularly preferably 2 to 5.

### —Other Fillers—

The inorganic filler may also include fillers other than silica particles, alumina particles, or calcium titanate particles.

The shape of such other fillers is not particularly limited, and examples thereof may include spherical, elliptical, and irregular shapes. In addition, such other fillers may be crushed.

Such other fillers may be subjected to surface processing.

One type of such other fillers may be used alone or two or more types of such other fillers may be used in combination. Such other fillers may also be a mixture of two or more types of fillers having different volume average particle sizes.

The type of such other fillers is not particularly limited. Specifically, the materials of such other fillers may include inorganic materials such as calcium carbonate, zirconium silicate, calcium silicate, silicon nitride, aluminum nitride, boron nitride, beryllia, zirconia, zircon, fosterite, steatite, spinel, mullite, titania, talc, clay, mica

As such other fillers, an inorganic filler with a flame retardant effect may be used. Examples of such inorganic filler with a flame retardant effect may include: aluminum hydroxide, magnesium hydroxide, complex metal hydroxides such as magnesium and zinc complex hydroxide, zinc borate, etc.

Such other fillers may also include titanium compound particles other than calcium titanate particles. Examples of the titanium compound particles other than calcium titanate particles may include strontium titanate particles, barium titanate particles, potassium titanate particles, magnesium titanate particles, lead titanate particles, aluminum titanate particles, lithium titanate, titanium oxide particles, etc.

However, from the perspective of suppressing the dielectric loss tangent of the cured article to be low, the content ratio of the barium titanate particles is preferably less than 1% by volume, more preferably less than 0.5% by volume, and even more preferably less than 0.1% by volume, with respect to the entirety of the inorganic filler. That is, the inorganic filler preferably does not include barium titanate particles, or preferably includes the barium titanate particles in the above content ratio.

In addition, the total content ratio of the titanium compound particles other than calcium titanate particles, with respect to the entirety of the inorganic filler, may be 1% by volume, 0.5% by volume, or 0.1% by volume. That is, it may also be that the inorganic filler does not include the titanium compound particles other than calcium titanate particles or includes the titanium compound particles other than calcium titanate particles in the above content ratio.

The preferable ranges of the volume average particle size of the other fillers are the same as the preferred ranges of the volume average particle sizes of the silica particles and the alumina particles.

### —Content Ratio and Properties of the Entirety of the Inorganic Filler—

From the perspective of controlling the flowability and the strength of the cured article of the resin composition for molding, the content ratio of the entirety of the inorganic filler included in the resin composition for molding, with respect to the entirety of the resin composition for molding, is preferably more than 60% by volume and preferably more than 60% by volume and equal to or less than 90% by volume, more preferably 62% by volume to 85% by volume, even more preferably 65% by volume to 85% by volume, particularly more preferably 68% by volume to 80% by volume, and highly preferably 70% by volume to 78% by volume.

The content ratio (% by volume) of the inorganic filler in the resin composition for molding can be obtained by using the following method.

A thin sheet sample of the cured article of the resin composition for molding is photographed with a scanning electron microscope (SEM). An arbitrary area S is specified in the SEM image, and a total area A of the inorganic filler included in the area S is calculated. The value obtained by dividing the total area A of the inorganic filler is divided by the area S is converted into a percentage (%), and the value is defined as the content ratio (% by volume) of the inorganic filler in the resin composition for molding.

The area S is set to be sufficiently large relative to the size of the inorganic filler. For example, the area is set to include 100 or more inorganic fillers. The area S may be the total of multiple cut surfaces.

The inorganic filler may have a biased presence ratio in the gravity direction when the resin composition for molding is cured. In such case, at the time of imaging by using the SEM, the entirety is imaged in the gravity direction of the cured article, and the area S in which the entirety of the cured article in the gravity direction is included is specified.

The relative dielectric constant at 10 GHz in the entirety of the inorganic filler is, for example, within the range of being equal to or less than 80. In the following, the relative dielectric constant at 10 GHz is simply referred to as “dielectric constant”.

As a method for setting the dielectric constant for the entirety of the inorganic filler is equal to or less than 80, examples may include a method of using unsintered calcium titanate particles as the calcium titanate particles. Here, the unsintered calcium titanate particles refer to calcium titanate particles that have not been exposed to a temperature equal to or higher than 1000° C. after being synthesized.

By sintering calcium titanate particles at a temperature equal to or higher than 1000° C., the dielectric constant thereof increases significantly. For example, the dielectric constant after the unsintered calcium titanate particles are sintered at 1000° C. for two hours becomes a value equal to or more than 10 times of the dielectric constant of the calcium titanate particles before sintering.

From the perspective of suppressing the dielectric loss, the dielectric constant of the entirety of the inorganic filler is preferably equal to or less than 50, more preferably equal to or less than 40, and even more preferably equal to or less than 30. From the perspective of miniaturizing an electronic component, such as an antenna, the dielectric constant of the entirety of the inorganic filler is preferably equal to or more than 5, more preferably equal to or more than 10, and even more preferably equal to or more than 15. From the perspective of suppressing the dielectric loss and miniaturizing an electronic component, such as an antenna, the dielectric constant of the entirety of the inorganic filler is preferably 5 to 50, more preferably 10 to 40, and even more preferably 15 to 30.

Here, the dielectric constant of the entirety of the inorganic filler is obtained according to the following, for example.

Specifically, three or more types of resin compositions for measurement, which include the inorganic filler as the measurement target and a specific curable resin and have different content ratios of the inorganic filler, and a resin composition for measurement that includes the specific curable resin but does not include the inorganic filler are prepared. As the resin compositions for measurement that include the inorganic filler as the measurement target and the specific curable resin, examples may include resin compositions for measurement including a biphenyl aralkyl epoxy resin, a phenol curing agent which is a phenol aralkyl phenol resin, a curing accelerator including organic phosphine, and the inorganic filler under measurement. In addition, as the three or more types of resin compositions for measurement with different inorganic filler content amounts, examples may include resin compositions for measurement in which the content ratios of the inorganic filler are 10% by volume, 20% by volume, and 30% by volume with respect to the entirety of the resin compositions for measurement.

Each resin composition for measurement that is prepared is molded under the conditions of a molding temperature at 175° C., a molding pressure of 6.9 MPa, and a curing duration of 600 sec. through compression molding, and the cured articles for measurement are respectively obtained. The relative dielectric constant at 10 GHz for each cured article for measurement that is obtained is measured, and a graph plotted by using the content ratio of the inorganic filler as the horizontal axis and the measurement value of the relative dielectric constant as the vertical axis is generated. From the obtained graph, a straight line is approximated by the least squares method, and the relative dielectric constant when the content ratio of the inorganic filler is 100% by volume is determined by extrapolation and taken as the “dielectric constant of the entirety of the inorganic filler.”

### [Various Additives]

The resin composition for molding in the embodiment may include, in addition to the above components, various additives such as a coupling agent, an ion exchanger, a release agent, a flame retardant, a colorant, and a stress relaxation agent, etc., as exemplified below. The resin composition for molding in the embodiment may also include various conventional additives, as needed, in addition to the additives exemplified below.

### (Coupling Agent)

The resin composition for molding in the embodiment may include a coupling agent. From the perspective of increasing the adhesive property between the resin component and the inorganic filler, the resin composition for molding preferably includes a coupling agent. As the coupling agent, examples may include a conventional coupling agent, such as silane-based compounds like epoxysilane, mercaptosilane, aminosilane, alkylsilane, ureidosilane, vinylsilane, and disilazane, titanium-based compounds, aluminum chelate-based compounds, and aluminum/zirconium-based compounds.

In the case where the resin composition for molding includes a coupling agent, the amount of the coupling agent is preferably 0.05 parts by mass to 5 parts by mass, and more preferably 0.1 parts by mass to 2.5 parts by mass, with respect to 100 parts by mass of the inorganic filler. When the amount of the coupling agent is equal to or more than 0.05 parts by mass with respect to 100 parts by mass of the inorganic filler, the adhesive property with a frame tends to increase. When the amount of the coupling agent is equal to or less than 5 parts by mass with respect to 100 parts by mass of the inorganic filler, the moldability of the package tends to increase.

### (Ion Exchanger)

The resin composition for molding in the embodiment may include an ion exchanger. For the perspective of improving the moisture resistance and the high temperature placement property of an electronic component device including a sealed electronic component, the resin composition for molding preferably includes an ion exchanger. The ion exchanger is not particularly limited, and a conventional ion exchanger can be used. Specifically, examples include hydrotalcite compounds, and oxide hydrates of at least one element selected from the group consisting of magnesium, aluminum, titanium, zirconium, and bismuth. One type of the ion exchanger may be used alone or two or more types of the ion exchangers may be used in combination. Among these, hydrotalcite represented by a General Formula (A) as follows is preferred:

Mg_{(1-X)}Al_{X}(OH)₂(CO₃)_{X/2}·mH₂O (A)
(0<X≤0.5, where m is a positive number)

In the case where the resin composition for molding includes the ion exchanger, the content thereof is not particularly limited as long as it is an amount sufficient to capture ions such as halogen ions. For example, the content of the ion exchanger is preferably 0.1 parts by mass to 30 parts by mass, and more preferably 1 part by mass to 10 parts by mass, with respect to 100 parts by mass of the resin component.

### (Release Agent)

From the perspective of having favorable releasability with a mold at the time of molding, the resin composition for molding in the embodiment may include a release agent. The release agent is not particularly limited, and a conventional release agent can be used. Specifically, examples may include carnauba wax, higher fatty acids such as montanic acid and stearic acid, higher fatty acid metal salts, ester waxes such as montanic acid esters, polyolefin waxes such as oxidized polyethylene and non-oxidized polyethylene, etc. One type of the release agent may be used alone or two or more types of the release agents may be used in combination.

In the case where the resin composition for molding includes a release agent, the amount of the release agent is preferably 0.01 parts by mass to 10 parts by mass, and is more preferably 0.1 parts by mass to 5 parts by mass, with respect to 100 parts by mass of the resin component. When the amount of the release agent is 0.01 parts by mass or more with respect to 100 parts by mass of the resin component, there is a tendency that sufficient releasability is attained, and when the amount is 10 parts by mass or less, a more favorable adhesive property tends to be attained.

### (Flame Retardant).

The resin composition for molding in the embodiment may include a flame retardant. The flame retardant is not particularly limited, and a conventional flame retardant can be used. Specifically, examples may include organic or inorganic compounds containing halogen atoms, antimony atoms, nitrogen atoms, or phosphorus atoms, metal hydroxides, etc. One type of the flame retardant may be used alone or two or more types of the flame retardants may be used in combination.

In the case where the resin composition for molding includes the flame retardant, the content thereof is not particularly limited as long as it is an amount sufficient to attain a desired flame retardant effect. For example, the content of the flame retardant is preferably 1 part by mass to 30 parts by mass, and more preferably 2 parts by mass to 20 parts by mass, with respect to 100 parts by mass of the resin component.

### (Colorant)

The resin composition for molding in the embodiment may include a colorant. As the colorant, examples can include conventional colorants such as carbon black, organic dyes, organic pigments, titanium oxide, red lead, and rough. The content amount of the colorant can be selected as appropriate in accordance with the needs. One type of the colorant may be used alone or two or more types of the colorants may be used in combination.

### (Stress Relaxation Agent)

The resin composition for molding in the embodiment may include a stress relaxation agent. By including a stress relaxation agent, the occurrence of a package warpage and a package crack can be further reduced. As the stress relaxation agent, examples may include a conventional stress relaxation agent (flexibilizer) that is generally used. Specifically, examples may include thermoplastic elastomers such as silicone, styrene, olefin, urethane, polyester, polyether, polyamide, and polybutadiene, indene-styrene-coumarone copolymers, etc., organophosphorus compounds such as triphenylphosphine oxide and phosphate esters, rubber particles such as natural rubber (NR), acrylonitrile-butadiene rubber (NBR), acrylic rubber, urethane rubber, and silicone powder, and rubber particles having a core-shell structure, such as methyl methacrylate-styrene-butadiene copolymer (MBS), methyl methacrylate-silicone copolymer, and methyl methacrylate-butyl acrylate copolymer. One type of the stress relaxation agent may be used alone or two or more types of the stress relaxation agents may be used in combination.

As a silicone-based stress relaxation agent, examples may include those having an epoxy group, those having an amino group, and those modified with polyether. More preferred are silicone compounds such as silicone compounds having an epoxy group and polyether-based silicone compounds.

From the perspective of dielectric loss tangent, the stress relaxation agent includes at least one of an indene-styrene-cumarone copolymer and a triphenylphosphine oxide.

In the case where the resin composition for molding includes a stress relaxation agent, the amount of the stress relaxation agent is preferably 1 part by mass to 30 parts by mass, and is more preferably 2 parts by mass to 20 parts by mass, with respect to 100 parts by mass of the resin component.

In the case where the stress relaxation agent includes at least one of the indene-styrene-cumarone copolymer and the triphenylphosphine oxide, the total amount thereof is preferably 1 part by mass to 30 parts by mass, more preferably 2 parts by mass to 20 parts by mass, in the 100 parts by mass of the resin component.

The content amount of the indene-styrene-cumarone copolymer may be, for example, 1 part by mass to 20 parts by mass, and may also be 2 parts by mass to 10 parts by mass, with respect to 100 parts by mass of the resin component.

The content amount of the triphenylphosphine oxide may be, for example, 1 part by mass to 30 parts by mass, and may also be 5 parts by mass to 15 parts by mass, with respect to 100 parts by mass of the resin component.

The content amount of the silicone-based stress relaxation agent may be, for example, 2 parts by mass or less, and may also be 1 part by mass or less, with respect to 100 parts by mass of the resin component. It may also be that the resin composition for molding does not contain the silicone-based stress relaxation agent. From the perspective of dielectric loss tangent, in the resin composition for molding, the stress relaxation agent includes at least one (preferably both) of the indene-styrene-cumarone copolymer and the triphenylphosphine oxide, and preferably does not include the silicone-based stress relaxation agent. The lower limit of the content amount of the silicone-based stress relaxation agent is not particularly limited, and may be 0 part by mass, and may also be 0.1 parts by mass.

From the perspective of dielectric loss tangent, the content ratio of the silicone-based stress relaxation agent is preferably 20% by mass or less, more preferably 10% by mass, even more preferably 7% by mass, particularly preferably 5% by mass, highly preferably 0.5% by mass, and highly preferably 0.1% by mass. The lower limit of the content ratio of the silicone-based stress relaxation agent is not particularly limited, and may be 0% by mass, and may also be 0.1% by mass.

### <Method for Preparing the Resin Composition for Molding>

The method for preparing the resin composition for molding is not particularly limited. As a general means, examples can include a method of sufficiently mixing the components in predetermined amounts by using a mixer, etc., and then melt-kneading the mixture by using a mixing roll, an extruder, etc., and cooling, and pulverizing the mixture. More specifically, examples can include a method of stirring and mixing the predetermined amounts of the components, kneading the mixture by using a kneader, a roll, an extruder, etc., preheated to 70° C. to 140° C., cooling, and pulverizing the mixture.

The resin composition for molding in the embodiment is preferably solid at room temperature and normal pressure (e.g., 25° C., and atmospheric pressure). The shape in the case where the resin composition for molding is a solid is not particularly limited, and examples may include powder, granules, and tablets, etc. Regarding the mass and the dimension in the case where the resin composition for molding is in a tablet shape, from the perspective of handling properties, it is preferable to adjust the dimension and mass to meet the molding condition of the package.

### <Properties of the Resin Composition for Molding>

The relative dielectric constant of the cured article at 10 GHz obtained by being molded through compression molding on the resin composition for molding according to the embodiment under the conditions of the mold temperature of 175° C., the molding pressure of 6.9 MPa may be 5 to 30, for example. From the perspective of miniaturizing the electronic component, such as an antenna, the relative dielectric constant of the cured article at 10 GHz is preferably 6 to 20, more preferably 7 to 15, and even more preferably 8 to 15.

The measurement of the relative dielectric constant is carried out at the temperature of 25±3° C. by using a dielectric constant measurement device (i.e., product name “Network Analyzer N5227A”, manufactured by Agilent Technologies).

The dielectric loss tangent of the cured article at 10 GHz obtained by being molded through compression molding on the resin composition for molding according to the embodiment under the conditions of the mold temperature of 175° C., the molding pressure of 6.9 MPa may be 0.015, for example. From the perspective of reducing transmission loss, the dielectric loss tangent of the cured article at 10 GHz is preferably 0.007 or less, and more preferably 0.005 or less.

The lower limit of the dielectric loss tangent of the cured article at 10 GHz is not particularly limited, and may be, for example, 0.001.

The measurement of the dielectric loss tangent is performed at the temperature of 25±3° C. by using a dielectric constant measurement device (i.e., product name “Network Analyzer N5227A”, manufactured by Agilent Technologies).

The flowing distance at the time of molding under the conditions of the mold temperature of 175° C., the molding pressure of 6.9 MPa, and the curing time of 90 sec. by using a spiral flow measurement mold following EMMI-1-66 is preferably 80 cm or more, more preferably 100 cm or more, and even more preferably 120 cm or more. In the following, the flowing distance is referred to as “spiral flow”. The upper limit of the spiral flow is not particularly limited, and may be, for example, 200 cm.

The gelation time of the resin composition for molding at 175° C. is preferably 30 sec. to 100 sec., more preferably 40 sec. to 70 sec.

The gelation time measurement at 175° C. is performed as follows. Specifically, a sample of 3 g of the resin composition for molding is measured at 175° C. by using a Curastometer manufactured by JSR Trading Co., Ltd., and the time until the torque curve rises is set as the gelation time (sec).

### <Use of the Resin Composition for Molding>

The resin composition for molding according to the embodiment can be used, for example, in the manufacture of electronic component devices, particularly high frequency devices, as described below. The resin composition for molding according to the embodiment may be used to seal electronic components in high frequency devices.

In particular, in recent years, with the wide-spreading of the fifth-generation mobile communication systems (5G), semiconductor packages (PKGs) used in electronic component devices have become more highly functional and miniaturized. As PKGs become more miniaturized and functional, the development is also underway for antennas in package (AiP), which is a kind of PKGs with an antenna function. In an AiP, in order to cope with the increase in the number of channels due to the diversification of information, the frequency of radio waves used for communication has increased, and in sealing materials, there is a demand for both a high dielectric constant and a low dielectric tangent.

With the resin composition for molding according to the embodiment, as described above, a cured article with a high dielectric constant and a low dielectric tangent is obtained. Therefore, in high frequency devices, the composition is particularly suitable for use as an antenna-in-package (AiP) in which an antenna disposed on a support member is sealed with the resin composition for molding.

In an electronic component device including an antenna, such as an antenna-in-package, if an amplifier for power supply is provided on the opposite side to the antenna, heat is generated due to power supply. From the perspective of facilitating heat dissipation, the resin composition for molding used for the manufacture of electronic component devices preferably includes alumina articles as the inorganic filler.

### <Electronic Component Device>

An electronic component device according to an embodiment of the disclosure includes a support member, an electronic component disposed on the support member, and the cured article of the resin composition for molding that seals the electronic component.

Examples of the electronic component device may include those (e.g., high frequency devices) in which the electronic component (an active element such as a semiconductor chip, a transistor, a diode, a thyristor, etc., a passive element such as a capacitor, a resistor, and a coil, or an antenna, etc.) is mounted on the support member, such as a lead frame, a pre-wired tape carrier, a wiring board, glass, a silicon wafer, an organic substrate, etc., and a resulting electronic component region is sealed by using the resin composition for molding.

The type of the support member is not particularly limited, and a support member generally used in the manufacture of an electronic component device can be used.

The electronic component may include an antenna, and may also include an antenna and an element other than an antenna. The antenna is not limited as long as it can function as an antenna, and may be an antenna element or a wiring.

In the electronic component device according to the embodiment, where necessary, other electronic components may also be disposed on the surface opposite to the surface where the electronic component is disposed on the support member. Such other electronic components may be sealed by the resin composition for molding, by other resin compositions, or not sealed.

### <Manufacturing Method of the Electronic Component Device>

A manufacturing method of the electronic component device according to the embodiment includes: a process of disposing the electronic component on the support member; and a process of sealing the electronic component by using the resin composition for molding.

The method for carrying out each of the processes is not particularly limited, and the method can be carried out through general means. In addition, the types of the support member and the electronic component used in the manufacture of the electronic component device are not particularly limited, and support members and electronic components conventionally used in the manufacture of electronic component devices can be used.

As a method for sealing the electronic component by using the resin composition for molding, examples may include low pressure transfer molding, injection molding, compression molding, etc. Among the above, low pressure transfer molding is generally adopted.

### EXAMPLES

The embodiment will be described in detail with the examples, but the scope of the embodiment is not limited to these examples.

### <Preparation of the Resin Composition for Molding>

The components shown below were mixed in the blending ratios (parts by mass) shown in Tables 1 to 3 to prepare the resin compositions for molding of Examples and Comparative Examples. The resin compositions for molding are solids at room temperature and normal pressure.

In Tables 1 to 3, blank spaces indicate that corresponding components are not included.

In addition, the results of the content ratio of the calcium titanate particles with respect to the entirety of the used inorganic filler (Content ratio (% by volume) in the tables), the content ratio of the inorganic filler with respect to the entirety of the resin composition for molding (Content ratio (% by volume) in the tables), and the relative dielectric constant of the entirety of the inorganic filler at 10 GHz (Filler dielectric constant in the tables) obtained by using the above methods are also shown in Tables 1 to 3.
Epoxy resin 1: o-cresol novolac epoxy resin, epoxy equivalent 200 g/eq (“N500P” manufactured by DIC Corporation)
Epoxy resin 2: biphenyl aralkyl epoxy resin, epoxy equivalent 274 g/eq (Nippon Kayaku Co., Ltd., product name “NC-3000”)
Epoxy resin 3: biphenyl epoxy resin, epoxy equivalent 192 g/eq (Mitsubishi Chemical Corporation, product name “YX-4000”)
Curing agent 1: Active ester compound, DIC Corporation, product name “EXB-8”
Curing agent 2: Phenol curing agent, phenol aralkyl resin, hydroxyl equivalent 170 g/eq (Meiwa Kasei Co., Ltd., product name “MEH7851 series”)
Inorganic filler 1: Alumina particles, volume average particle size: 5.7 μm, shape: spherical
Inorganic filler 2: Alumina particles, volume average particle size: 0.7 μm, shape: spherical
Inorganic filler 3: Unsintered calcium titanate particles, volume average particle size: 8.9 μm, shape: irregular
Inorganic filler 4: Unsintered calcium titanate particles, volume average particle size: 0.2 μm, shape: irregular
Curing accelerator: triphenylphosphine/1,4-benzoquinone adduct
Coupling agent: N-phenyl-3-aminopropyltrimethoxysilane (Shin-Etsu Chemical Co., Ltd., product name “KBM-573”)
Release agent: Montanic acid ester wax (Clariant Japan Co., Ltd., product name “HW-E”)
Colorant: Carbon black (Mitsubishi Chemical Corporation, product name “MA600”)
Stress relaxation agent 1: Polyether silicone compound (Momentive Performance Materials, product name “SIM768E”)
Stress relaxation agent 2: Indene-styrene-coumarone copolymer
Stress relaxation agent 3: Triphenylphosphine oxide

The volume average particle size of each of the inorganic fillers is a value obtained by the following measurement.

Specifically, firstly, the inorganic filler was added to a dispersion medium (water) in an amount of 0.01% by mass to 0.1% by mass, and the mixture was dispersed in a bath-type ultrasonic cleaner for 5 minutes.

5 ml of the obtained dispersion liquid was poured into a cell, and the particle size distribution was measured at 25° C. by using a laser diffraction/scattering particle size distribution measurement device (HORIBA, Ltd., LA920).

The particle size at an integral value of 50% (volume basis) in the obtained particle size distribution was defined as the volume average particle size.

### <Evaluation of the Resin Composition for Molding>

### (Relative Dielectric Constant and Dielectric Loss Tangent)

The resin composition for molding was charged into a vacuum hand press machine and molded under the conditions of the mold temperature of 175° C., the molding pressure of 6.9 MPa, and the curing time of 600 seconds. Post-curing was carried out at 175° C. for 6 hours to obtain a plate-shaped cured article (12.5 mm in length, 25 mm in width, 0.2 mm in thickness). The plate-shaped cured article was used as a test piece, and the relative dielectric constant and dielectric loss tangent were measured at a temperature of 25±3° C. and 10 GHz by using a dielectric constant measurement device (Agilent Technologies, product name “Network Analyzer N5227A”). The results are shown in Tables 1 to 3 (“Relative dielectric constant” and “Dielectric loss tangent” in the tables).

### (Flowability: Spiral Flow)

By using the spiral flow measurement mold following EMMI-1-66, the molding resin composition was molded under the conditions of the mold temperature of 180° C., the molding pressure of 6.9 MPa, and the curing time of 120 seconds, and the flowing distance (cm) was determined. The results are shown in Tables 1 to 3 (“Flowing distance (cm)” in the tables).

### (Thermal Conductivity)

The thermal conductivities of the resin compositions for molding were carried out according to the following. Specifically, by using the resin compositions for molding that had been prepared, transfer molding was performed under the conditions of the mold temperature of 180° C., the molding pressure of 7 MPa, and the curing time of 300 sec. The specific gravity (density, g/cm³) of the resulting cured article was measured by Archimedes' method. The thermal diffusivity (m²/s) of the resulting cured article was measured by a laser flash method by using a thermal diffusivity measurement device (NETZSCH, LFA467). The specific heat (J/(g·K)) of the cured article was theoretically calculated based on the literature value of the specific heat of each material constituting the resin composition for sealing and the blending ratio. From the measurement value, the thermal conductivity of the cured article was calculated according to Formula 2.

$$λ = α \times Cp \times d \qquad ( Formula 2 )$$

Here, λ represents thermal conductivity (W/(m·K)), α represents thermal diffusivity (m²/s), Cp represents specific heat (J/(g·K)), and p represents density (kg/m³).

### (Gelation Time)

3 g of the resin composition for molding was measured at 175° C. by using a Curastometer manufactured by JSR Trading Co., Ltd., and the time until the torque curve rises was set as the gelation time (sec). The results are shown in Tables 1 to 3 (“Gelation time (sec.)” in the tables). In the table, “not good” means that the gel time was too short that the rise in the torque curve could not be observed.

TABLE 1

| | | Example | Example | Example | Example | Example |
|---|---|---|---|---|---|---|
| | | 1 | 2 | 3 | 4 | 5 |
| Composition | Epoxy resin 1 | 70 | 70 | 70 | | |
| | Epoxy resin 2 | | | | 70 | 70 |
| | Epoxy resin 3 | 30 | 30 | 30 | 30 | 30 |
| | Curing agent 1 | 106 | 106 | 106 | 63.5 | 51.6 |
| | Curing agent 2 | | | | 40.3 | 32.8 |
| | Organic filler 1 | 1600 | 1750 | 1686 | 1586 | 1491 |
| | Organic filler 2 | | | | | |
| | Organic filler 3 | 337 | 247 | 292 | 334 | 314 |
| | Organic filler 4 | 225 | 157 | 180 | 223 | 209 |
| | Curing accelerator | 5 | 5 | 5 | 5 | 5 |
| | Coupling agent | 5 | 5 | 5 | 5 | 5 |
| | Release agent | 3 | 3 | 3 | 3 | 3 |
| | Coloring agent | 5 | 5 | 5 | 5 | 5 |
| | Stress relaxant 1 | | | | | 5 |
| | Stress relaxant 2 | 10 | 10 | 10 | 10 | 10 |
| | Stress relaxant 3 | 5 | 5 | 5 | 5 | 5 |
| | Total | 2401 | 2393 | 2397 | 2379.8 | 2236.4 |
| Filler | Particle ratio (% by volume) | 25 | 18 | 21 | 25 | 25 |
| | Content ratio (% by volume) | 73 | 73 | 73 | 73 | 73 |
| | Filler dielectric constant | 14.7 | 12.4 | 13.2 | 14 | 14.7 |
| Evaluation | Relative dielectric constant | 11.5 | 9.8 | 10.4 | 11.0 | 11.5 |
| | Dielectric loss tangent | 0.0033 | 0.0031 | 0.0031 | 0.0045 | 0.0050 |
| | Flowing distance (cm) | 105 | 105 | 90 | 85 | 120 |
| | Thermal conductivity | 1.8 | 2 | 1.9 | 1.8 | 1.8 |
| | (W/(m · K)) | | | | | |
| | Gelation time (sec.) | 50 | 55 | 53 | 48 | 60 |

TABLE 2

| | | Example | Example | Comparative | Comparative |
|---|---|---|---|---|---|
| | | 6 | 7 | example 1 | example 2 |
| Composition | Epoxy resin 1 | | | | |
| | Epoxy resin 2 | 70 | 70 | 70 | 70 |
| | Epoxy resin 3 | 30 | 30 | 30 | 30 |
| | Curing agent 1 | 51.6 | 51.6 | 51.6 | 51.6 |
| | Curing agent 2 | 32.8 | 32.8 | 32.8 | 32.8 |
| | Organic filler 1 | 1557 | 1359 | 1750 | 809 |
| | Organic filler 2 | | | 185 | |
| | Organic filler 3 | 328 | 286 | | 170 |
| | Organic filler 4 | 219 | 191 | | 114 |
| | Curing accelerator | 5 | 5 | 5 | 5 |
| | Coupling agent | 5 | 5 | 5 | 5 |
| | Release agent | 3 | 3 | 3 | 3 |
| | Coloring agent | 5 | 5 | 5 | 5 |
| | Stress relaxant 1 | 15 | | | |
| | Stress relaxant 2 | 10 | | 10 | 10 |
| | Stress relaxant 3 | 5 | | 5 | 5 |
| | Total | 2336.4 | 2038.4 | 2152.4 | 1310.4 |
| Filler | Particle ratio (% by | 25 | 25 | 0 | 25 |
| | volume) | | | | |
| | Content ratio (% by | 73 | 73 | 73 | 60 |
| | volume) | | | | |
| | Filler dielectric constant | 14.7 | 15.1 | 8.5 | 13.1 |
| Evaluation | Relative dielectric | 11.5 | 11.8 | 7.0 | 9.0 |
| | constant | | | | |
| | Dielectric loss tangent | 0.0060 | 0.0055 | 0.0050 | 0.0065 |
| | Flowing distance (cm) | 125 | 75 | 130 | 150 |
| | Thermal conductivity | 1.8 | 1.8 | 2.3 | 1.3 |
| | (W/(m · K)) | | | | |
| | Gelation time (sec.) | 70 | 45 | 50 | 45 |

TABLE 3

| | | Example | Example | Example | Example |
|---|---|---|---|---|---|
| | | 8 | 9 | 10 | 11 |
| Composition | Epoxy resin 1 | 70 | 70 | 70 | 70 |
| | Epoxy resin 2 | | | | |
| | Epoxy resin 3 | 30 | 30 | 30 | 30 |
| | Curing agent 1 | 74 | 74 | 74 | 74 |
| | Curing agent 2 | 30.2 | 30.2 | 30.2 | 30.2 |
| | Organic filler 1 | 1598 | 1617 | 1729 | 1630 |
| | Organic filler 2 | | | | |
| | Organic filler 3 | 335 | 339 | 362 | 341 |
| | Organic filler 4 | 224 | 227 | 243 | 229 |
| | Curing accelerator | 5 | 5 | 5 | 5 |
| | Coupling agent | 5 | 5 | 5 | 5 |
| | Release agent | 3 | 3 | 3 | 3 |
| | Coloring agent | 5 | 5 | 5 | 5 |
| | Stress relaxant 1 | 0.1 | 3 | 20 | |
| | Stress relaxant 2 | 10 | 10 | 10 | |
| | Stress relaxant 3 | 5 | 5 | 5 | 20 |
| | Total | 2394.3 | 2423.2 | 2591.2 | 2442.2 |
| Filler | Particle ratio (% by volume) | 25.9 | 25.9 | 25.9 | 25.9 |
| | Content ratio (% by volume) | 73 | 73 | 73 | 73 |
| | Filler dielectric constant | 14.7 | 14.7 | 14.7 | 14.7 |
| Evaluation | Relative dielectric constant | 11.5 | 11.6 | 11.5 | 11.5 |
| | Dielectric loss tangent | 0.0033 | 0.0034 | 0.0045 | 0.0030 |
| | Flowing distance (cm) | 105 | 110 | 105 | 115 |
| | Thermal conductivity | 1.8 | 1.8 | 1.7 | 1.7 |
| | (W/(m · K)) | | | | |
| | Gelation time (sec.) | 50 | 52 | 55 | 55 |

As shown in Tables 1 to 3, with the resin compositions for molding of the examples, compared with the comparative examples, a cured article having a low dielectric loss tangent tends to be obtained, while the relative dielectric constant tends to be maintained.

The disclosure of PCT/JP2022/016913, filed on Mar. 31, 2022, is incorporated by reference in its entirety into this specification.

All publications, patent applications, and standards mentioned in this specification are incorporated by reference into this specification to the same extent as if each individual publication, patent application, and standard was specifically and individually indicated to be incorporated by reference.

1. A resin composition for molding, comprising:
a curable resin;
an inorganic filler, comprising one of silica particles and alumina particles, and calcium titanate particles,
wherein a content ratio of the calcium titanate particles is 10% by volume or more and less than 30% by volume with respect to the entirety of the inorganic filler, and
a content ratio of the entirety of the inorganic filler is more than 60% by volume with respect to the entirety of the resin composition for molding.

2. The resin composition for molding as claimed in claim 1, wherein the curable resin comprises an epoxy resin, and the resin composition for molding further comprises a curing agent.

3. The resin composition for molding as claimed in claim 2, wherein the curing agent comprises an active ester compound.

4. The resin composition for molding as claimed in claim 3, wherein the curing agent further comprises a phenol curing agent.

5. The resin composition for molding as claimed in claim 2, wherein the epoxy resin comprises at least one of an o-cresol novolac epoxy resin, a biphenyl aralkyl epoxy resin, and a biphenyl epoxy resin.

6. The resin composition for molding as claimed in claim 1, wherein the inorganic filler comprises alumina particles.

7. The resin composition for molding as claimed in claim 1, further comprising a stress relaxation agent.

8. The resin composition for molding as claimed in claim 7, wherein the stress relaxation agent comprises at least one of an indene-styrene-coumarone copolymer and a triphenylphosphine oxide.

9. The resin composition for molding as claimed in claim 1, wherein a content ratio of a silicone-based stress relaxation agent is 5% by mass or less with respect to the entirety of the resin composition for molding.

10. The resin composition for molding as claimed in claim 8, wherein the resin composition for molding does not comprise a silicone-based stress relaxation agent.

11. The resin composition for molding as claimed in claim 1, wherein the resin composition for molding does not comprise titanium compound particles other than the calcium titanate particles.

12. The resin composition for molding as claimed in claim 1, wherein the resin composition for molding is used in a high frequency device.

13. The resin composition for molding as claimed in claim 12, wherein the resin composition for molding is used to seal an electronic component in the high frequency device.

14. The resin composition for molding as claimed in claim 1, wherein the resin composition for molding is used in an antenna-in-package.

15. An electronic component device, comprising:
a support member;
an electronic component, disposed on the support member; and
the resin composition for molding as claimed in claim 1, sealing the electronic component.

16. The electronic component device as claimed in claim 15, wherein the electronic component comprises an antenna.
